(19) United States
(12) Patent Application Publication
(10) Pub. No.: US 2025/0188604 A1
(43) Pub. Date: Jun. 12, 2025

(54) BORON NITRIDE FILM FORMING METHOD AND FILM FORMING APPARATUS

(71) Applicant: TOKYO ELECTRON LIMITED, Tokyo (JP)

(72) Inventors: Kazuki GOTO, Yamanashi (JP); Yoshihiro KATO, Yamanashi (JP); Shuichiro SAKAI, Yamanashi (JP)

(21) Appl. No.: 18/967,522

(22) Filed: Dec. 3, 2024

(30) Foreign Application Priority Data
Dec. 8, 2023 (JP) 2023-208011

(51) Int. Cl. C23C 16/34; C23C 16/44; C23C 16/455; C23C 16/52; H01J 37/32; H01L 21/02

(52) U.S. Cl. CPC C23C 16/342; C23C 16/4408; C23C 16/45538; C23C 16/45544; C23C 16/52; H01J 37/32449; H01L 21/0254; H01L 21/0262; H01J 37/32834; H01J 2237/332; H01L 21/02381

(57) ABSTRACT

A method of forming a boron nitride film includes performing plurality of sequences, each of the plurality of sequences including supplying a source gas containing a borazine-based compound and plasma to a substrate disposed inside a chamber and subsequently supplying the plasma to the substrate without the source gas, wherein each of at least a portion of the plurality of sequences includes supplying plasma of a hydrogen-free gas to the substrate after the supplying the plasma without the source gas. The supplying the source gas containing the borazine-based compound and the plasma includes supplying the source gas and plasma of a hydrogen-containing gas to the substrate, and the supplying the plasma without the source gas includes supplying the plasma of the hydrogen-containing gas without the source gas.

### CROSS-REFERENCE TO RELATED APPLICATION

This application is based upon and claims the benefit of priority from Japanese Patent Application No. 2023-208011, filed on Dec. 8, 2023, the entire contents of which are incorporated herein by reference.

### TECHNICAL FIELD

The present disclosure relates to a boron nitride film forming method and a film forming apparatus.

### BACKGROUND

As a boron nitride (BN) film forming method, for example, methods disclosed in Patent Documents 1 to 3, are known.

Patent Document 1 discloses a technique for generating plasma of a boron-containing gas and nitrogen gas and forming a hexagonal BN (h-BN) film on a surface of a substrate by plasma chemical vapor deposition (CVD) using plasma diffused from a plasma generation region. Patent Document 2 discloses a method of forming a conformal BN film by a process including a CVD step of performing at least a portion of deposition without plasma using a boron-containing gas and a step of exposing a deposited boron-containing film to plasma of a N-containing gas. Patent Document 3 discloses a method including forming a film having a borazine ring structure and containing boron and nitrogen on a substrate by intermittently performing a process of simultaneously performing supplying a borazine-based gas containing a ligand to the substrate and supplying a ligand desorption gas that desorbs the ligand from the substrate, under a condition in which the borazine ring structure in the borazine-based gas is held. In Patent Document 3, a NH₃ gas is used as the ligand desorption gas, and plasma of a N₂ gas, which is an inert gas, is used during film formation.

### PRIOR ART DOCUMENTS

### Patent Documents

Patent Document 1: Japanese Laid-Open Patent Publication No. 2020-147826
Patent Document 2: U.S. Pat. No. 8,288,292
Patent Document 3: Japanese Laid-Open Patent Publication No. 2016-063007

### SUMMARY

According to one embodiment of the present disclosure, a method of forming a boron nitride film includes performing plurality of sequences, each of the plurality of sequences including supplying a source gas containing a borazine-based compound and plasma to a substrate disposed inside a chamber and subsequently supplying the plasma to the substrate without the source gas, wherein each of at least a portion of the plurality of sequences includes supplying plasma of a hydrogen-free gas to the substrate after the supplying the plasma without the source gas. The supplying the source gas containing the borazine-based compound and the plasma includes supplying the source gas and plasma of a hydrogen-containing gas to the substrate, and the supplying the plasma without the source gas includes supplying the plasma of the hydrogen-containing gas without the source gas.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a timing chart showing an example of a BN film forming method according to an embodiment.

FIG. 2 is a timing chart showing another example of the BN film forming method according to an embodiment.

FIG. 3 is a timing chart showing still another example of the BN film forming method according to an embodiment.

FIGS. 4A to 4C are diagrams for explaining a modification mechanism by plasma of a H-free gas.

FIGS. 5A to 5C are diagrams for explaining a film formation sequence of each of Samples 1 to 5 used in experiments confirming that film quality of a BN film is improved according to an embodiment.

FIG. 6 is a diagram showing absorbance of each of Samples 1 to 5 in a wavenumber region including a peak of h-BN (1380 cm⁻¹) measured by Fourier transform infrared spectroscopy (FT-IR).

FIG. 7 is a diagram showing absorbance of each of Samples 1 to 5 in a wavenumber region including a peak of NHx (3,300 to 3,500 cm⁻¹) measured by FT-IR.

FIG. 8 is a diagram showing absorbance of each of Samples 1 to 5 in a wavenumber region including a peak of BOH (around 3,200 cm⁻¹) measured by FT-IR.

FIG. 9 is a diagram showing a film composition and a B/N ratio of a BN film of each of Samples 1 to 5.

FIG. 10 is a diagram showing a k-value and a leakage current in each of Samples 1 to 5.

FIG. 11 is a diagram showing a relationship between an N₂ plasma modification time and a film density after NH₃ plasma.

FIG. 12 is a cross-sectional view showing an example of a film forming apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <History and Outline>

First, a history and outline will now be described.

A BN film is an insulating film with excellent properties, and applications thereof to various uses have been studied. In particular, the BN film are attracting attention as a low dielectric constant (low-k) insulating film capable of achieving a k-value of 3 or less. As the BN film, a hexagonal BN (h-BN) film with lateral orientation has good wet etching resistance and dry etching resistance.

Patent Document 1 described above discloses a method of forming the h-BN film. This method is CVD, and may not provide a sufficient film-formation property, adhesion or film quality. In addition, Patent Document 2 discloses that a conformal BN film is obtained by performing a CVD step of performing at least a portion of depositions without plasma using a boron-containing gas and then performing processing using plasma of a N-containing gas. However, Patent Document 2 did not disclose on obtaining an h-BN film having good adhesion, flatness and film quality. A film forming method disclosed in Patent Document 3 mainly relates to a film formation rate of the BN film and did not disclose on obtaining the h-BN film having good adhesion, flatness and film quality.

Therefore, in one embodiment of the present disclosure, based on a premise that a BN film is formed by performing a plurality of sequences, each of the plurality of sequences including an operation of supplying a source gas containing a borazine-based compound and plasma to a substrate disposed inside a chamber and subsequently, an operation of supplying the plasma to the substrate without the source gas, the following conditions are added. That is, all or a portion of the plurality of sequences include an operation of supplying plasma of a hydrogen-free gas to the substrate after the operation of supplying the plasma to the substrate without the source gas. Further, in the operation of supplying the source gas and the plasma and subsequently the operation of supplying the plasma, plasma of a hydrogen-containing gas is used as the plasma.

As described above, by using the plasma of the hydrogen-containing gas as the plasma supplied together with the source gas containing the borazine-based compound and the plasma to be subsequently supplied without the source gas, it is possible to obtain an h-BN film having good adhesion of a film to the substrate and good film surface flatness. In addition, by supplying the plasma of the hydrogen-free gas after supplying the plasma without the source gas, it is possible to remove hydrogen in the film and improve film quality.

### Detailed Embodiment

As described above, a BN film forming method according to an embodiment includes performing a plurality of sequences, each of the plurality of sequences including an operation of supplying a source gas containing a borazine-based compound and plasma to a substrate and subsequently supplying the plasma to the substrate without the source gas, in a state in which the substrate is disposed inside a chamber of a film forming apparatus. All or a portion of the plurality of sequences includes an operation of supplying plasma of a hydrogen-free gas to the substrate to perform a modification process after the operation of supplying the plasma without the source gas. In the operation of supplying the source gas and the plasma and the operation of supplying the plasma without the source gas, plasma of a hydrogen-containing gas is used as the plasma.

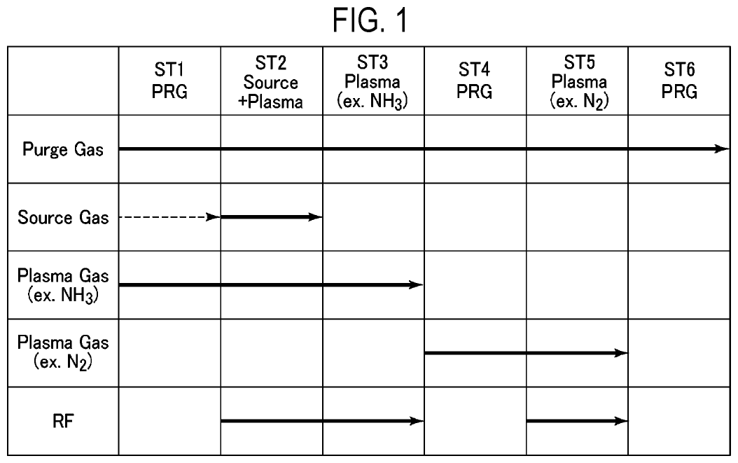

FIG. 1 is a timing chart showing an example of a sequence of a BN film forming method according to an embodiment. The sequence of FIG. 1 includes steps ST1, ST2, ST3, ST4, ST5, and ST6.

A substrate is not particularly limited but may be a semiconductor substrate as an example. The semiconductor substrate may be, for example, a substrate made only of a semiconductor such as Si or a substrate made of a semiconductor on which a desired film is formed.

In step ST1, an interior of the chamber is purged by supplying a purge gas into the chamber in which the substrate is disposed. At this time, in order to prepare a flow of a source gas, the source gas may flow into an exhaust line or the source gas may be filled into a fill tank. The purge gas may be an inert gas. A noble gas such as an Ar gas or a He gas may be preferably used as the purge gas. In addition, a plasma gas, which will be described later, may be simultaneously supplied.

In step ST2, the source gas containing the borazine-based compound and the plasma of the hydrogen (H)-containing gas are supplied to the substrate disposed inside the chamber. As a result, the source gas is adsorbed onto the substrate, and the source gas is activated by the plasma to promote adsorption. In FIG. 1, there is shown an example in which a NH₃ gas is supplied as the H-containing gas, and the plasma is generated by radio frequency (RF) power.

The borazine-based compound used as the source gas is a compound based on borazine (B₃H₆N₃) having a structure shown in Formula (1) below. That is, the borazine-based compound is a compound having, as a basic skeleton, a borazine ring in which three Bs and three Ns, which constitute borazine, are alternately bonded. For example, the borazine-based compound may be an organic borazine compound in which some or all of Hs of borazine are substituted with organic substituents. The organic borazine compound may be an alkylborazine compound using an alkyl group as an organic substituent, and may use, for example, trimethylborazine (TMB) having a structure shown in Formula (2) below. The source gas containing the borazine-based compound functions as a B source and an N source of the BN film.

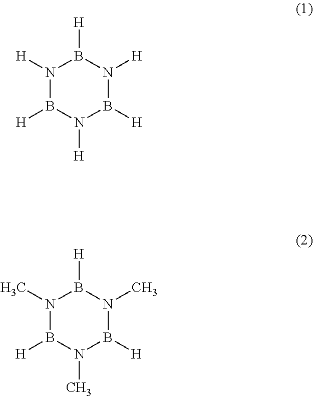

As long as the plasma of the H-containing gas is supplied to the substrate, the plasma may be generated inside the chamber or may be remotely generated elsewhere and introduced into the chamber. A plasma generation method is not particularly limited, but a capacitively-coupled plasma obtained by applying RF power to a parallel plate electrode to form an RF electric field in a processing space in which the substrate is disposed may be used. Alternatively, an inductively-coupled plasma and microwave plasma or the like may be used.

The plasma of the H-containing gas may be plasma of a gas containing H alone, such as a H₂ gas, but may also be plasma of a gas containing both H and N, for example, plasma of an ammonia (NH₃) gas (also called NH₃ plasma). Further, the plasma of the H-containing gas may be plasma of a gas containing NH₃ gas (e.g., NH₃+N₂ gas). When the plasma of the gas containing H and N is used, N in the plasma functions as an N source of the BN film. The plasma may be an energy that does not destroy the basic skeleton of the source gas when forming the h-BN film.

In step ST3, after step ST2, the supply of the source gas is stopped and only the plasma of the H-containing gas is supplied. Thus, adsorption of the source gas onto the substrate is promoted and reaction of the source gas adsorbed onto the substrate to h-BN is promoted. Step ST3 is performed continuously after step ST2. In this case, the plasma of the H-containing gas uses the same plasma as the plasma in step ST2.

The plasma of the H-containing gas, for example, the plasma of a NH₃-containing gas as the plasma in steps ST2 and ST3 is used to form the h-BN film. An H group or a NHx group is added into the film so that a discontinuous portion is generated in a borazine ring structure of h-BN in the in-plane of the film, which alleviates a stress difference with the substrate. This improves the adhesion of the BN film to the substrate and the surface flatness of the BN film.

In steps ST2 and ST3, temperature may be 200 to 400 degrees C. The h-BN is hardly to be formed as the temperature decreases. Pressure may be 4 Torr or more. However, when the pressure is 12 Torr or more, a film formation rate (growth per cycle (GPC)) tends to be too low. A time period (film-formation time period) in step ST2 may be 2 seconds or less. When the time period exceeds 2 sec, an amorphous BN component tends to increase. A time period (plasma time period) in step ST3 may be 4 seconds or more. When the time period is 4 seconds or more, the formation of lateral orientation of h-BN tends to be promoted. RF power used in the generation of the plasma in steps ST2 and ST3 may be 100 W or more. As the power becomes lower, the film quality tends to deteriorate.

In step ST4, the purge gas is supplied into the chamber to purge gas remaining in the chamber after step ST3. The purge gas may be an inert gas. A noble gas such as an Ar gas or a He gas may be preferably used as the purge gas. In step ST4, as shown in FIG. 1, gas not containing H (e.g., the N₂ gas) used in step ST5 to be described later may be supplied.

In step ST5, plasma of a H-free gas is supplied to the substrate to perform a modification process. As long as the plasma of the H-free gas is supplied to the substrate, the plasma of the H-free gas may be generated inside the chamber or may be remotely generated elsewhere and introduced into the chamber, like the plasma of the H-containing gas in steps ST2 and ST3. In a method of generating the plasma, although not particularly limited, capacitively-coupled plasma, inductively-coupled plasma, microwave plasma, or the like may be used as the plasma of the H-containing gas. The plasma of the H-free gas may be, for example, plasma of a N₂ gas (also called N₂ plasma) or plasma of a noble gas such as an Ar gas. Further, the plasma of the H-free gas may be plasma containing both the N₂ gas and the noble gas. The modification process using the plasma of the H-free gas in step ST5 may reduce H in the film to improve the film quality of the BN film.

In step ST5, the temperature may be 200 to 400 degrees C., as in steps ST2 and ST3. The pressure may be 6 Torr or more. A time period (modification process time period) in step ST5 may be 1 seconds or more. RF power used in the generation of the plasma in step ST5 may be 400 W or more.

In step ST6, the purge gas is supplied into the chamber to purge gas remaining in the chamber after step ST5. The purge gas may be an inert gas. A noble gas such as an Ar gas or a He gas may be preferably used as the purge gas.

By the above sequence including steps ST1 to ST6, a thin h-BN unit film is formed. Further, by performing the sequence including steps ST1 to ST6 multiple times, the h-BN film having a desired thickness is formed.

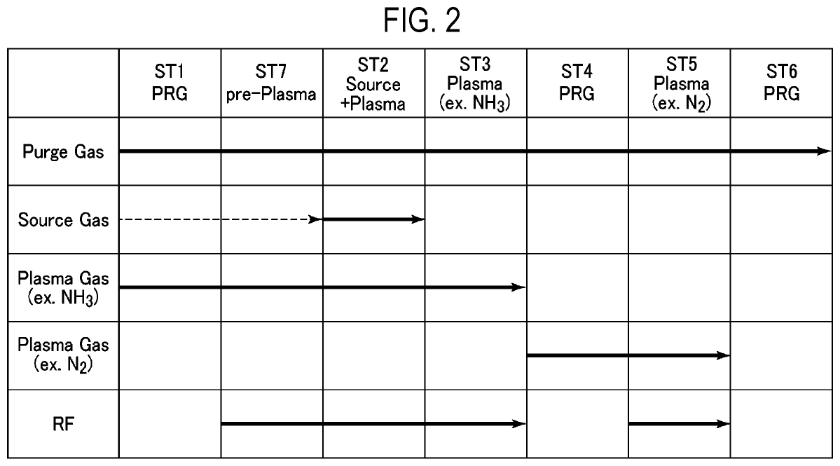

Instead of the sequence including steps ST1 to ST6, as illustrated in FIG. 2, a pre-plasma step (step ST7) of performing plasma processing on the substrate may be added prior to step ST2. Step ST7 is provided to improve the surface smoothness of the BN film to be formed. The pre-plasma step (step ST7) may be performed similar to step ST3.

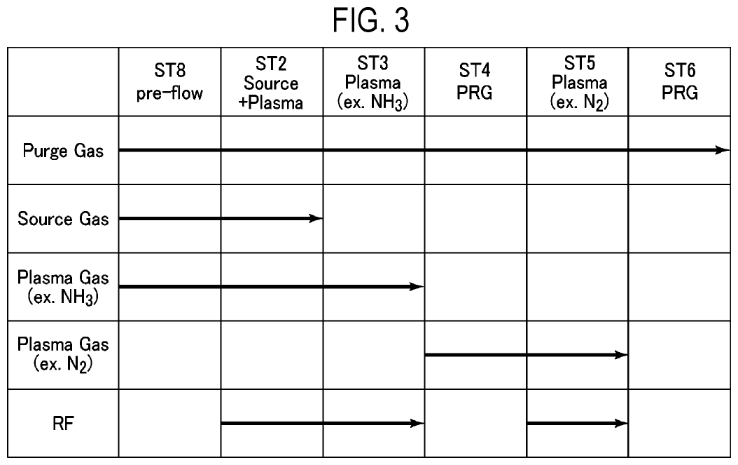

Further, as shown in FIG. 3, instead of step ST1, a pre-flow step (step ST8) of supplying a borazine-based compound gas to the substrate may be performed prior to step ST2. The pre-flow step (step ST8) is performed by supplying the borazine-based compound gas as in step ST2 without using plasma. The pre-flow step (step ST8) is provided to increase a step coverage of the BN film to be formed. In step ST8, the purge gas such as the noble gas may be supplied together with the borazine-based compound gas. In addition, a plasma gas may further be supplied.

In the embodiment, in any sequence of FIGS. 1 to 3, step ST2 of supplying the source gas and the plasma of the H-containing gas, step ST3 of supplying the plasma of the H-containing gas alone, and step ST5 of supplying the plasma of the H-free gas to perform the modification process are included. By steps ST2 and ST3, the h-BN film having good film adhesion and flatness may be formed. However, when H is included in the film, the film quality deteriorates. Accordingly, in step ST5, the modification process is performed by the plasma of the H-free gas to improve the film quality.

Hereinafter, details will be described.

In the embodiment, the source gas containing the borazine-based compound is supplied to the substrate to be adsorbed onto the substrate. Ligand is removed while maintaining a borazine skeleton of the borazine-based compound so that the h-BN film of a two-dimensional structure may be formed. In this case, by supplying the plasma in addition to the source gas, the borazine-based compound is activated, and adsorption and reaction of the source gas are promoted. Further, the reaction is further promoted by continuously supplying the plasma alone. Thus, the h-BN film may be formed at a high GPC.

In this case, the H-containing gas is used as the gas for plasma generation. A H group or a NHx group is included in the film by the plasma of the H-containing gas so that the discontinuous portion is generated in the borazine ring structure of h-BN in the in-plane of the film. This alleviates a stress difference with the substrate. Thus, the adhesion of the film to the substrate and the surface flatness of the film are improved as compared to the case in which the H-free gas is used as the gas for plasma generation. In this case, the gas containing H and N such as a NH₃ gas is used as the plasma of the H-containing gas, N in the plasma functions as an N source of the BN film, and the adhesion of the film to the substrate and the surface flatness of the film may be improved.

However, it has been found that, since H is included in the plasma in steps ST2 and ST3, H in the film is increased, which causes a problem in the film quality due to an increase in a B/N ratio of the BN film, deterioration of oxidation resistance or the like.

In contrast, the plasma of the H-free gas is supplied in step ST5 to perform the modification process so that H or an H-containing group is desorbed from the borazine-based compound in a gas phase and in the film. As a result, it was found that the film is modified and the H in the film is reduced, which improves the film quality and the lateral orientation.

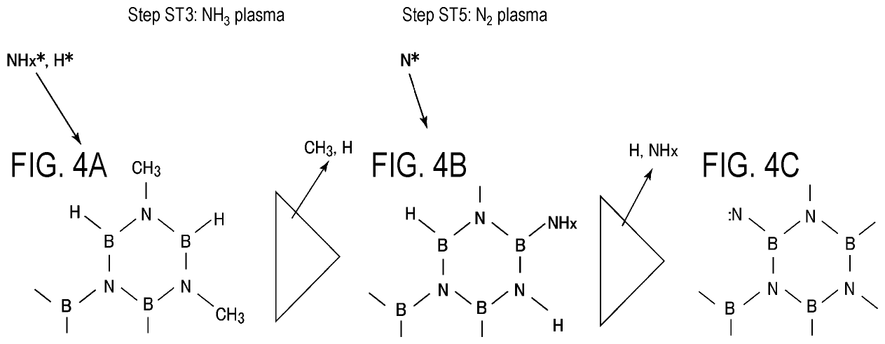

A mechanism for modifying the film will now be described with reference to FIGS. 4A to 4C.

A case in which TMB is used as the borazine-based compound in step ST2, NH₃ plasma is used as the plasma of the H-containing gas in steps ST2 and ST3, and N₂ plasma is used as the plasma of the H-free gas in step ST5 is described by way of example.

First, in step ST3, the NH₃ plasma is supplied to TMB in the gas phase and in the film, which has a structure generated in step ST2 as illustrated in FIG. 4A, CH₃ or H is desorbed from the TMB in the gas phase and in the film by the action of NHx* or H* in the plasma. As a result, a structure as illustrated in FIG. 4B is obtained. Thereafter, in step ST5, the N₂ plasma is supplied to the structure as illustrated in FIG. 4B, H or NHx is desorbed from the structure of FIG. 4B or replaced with N: by the action of N* in the plasma. As a result, a structure as illustrated in FIG. 4C. The structure of FIG. 4C has an adsorption site for TMB. In a subsequent step, TMB is supplied to promote the adsorption of TMB. This reduces H in the BN film and improves the film quality. In addition, the lateral orientation is also improved. Specifically, as the improvement in the film quality, an improvement in oxidation resistance, an implement of the BN ratio close to stoichiometric composition, a reduction in k-value and leakage current, and an increase in film density are obtained.

Experiments through which these results were confirmed will be described.

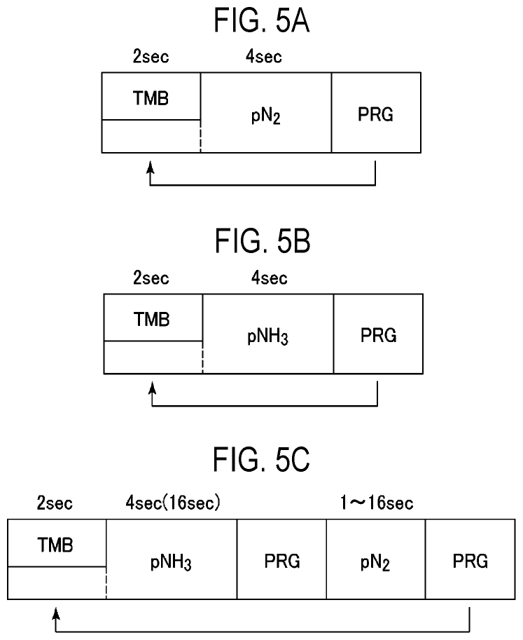

Here, as shown in FIG. 5A, in Sample 1, the BN film was formed on the substrate by repeating a sequence including TMB+N₂ plasma (TMB+pN₂), N₂ plasma (pN₂), and purging (PRG) multiple times. As shown in FIG. 5B, in Sample 2, the BN film was formed on the substrate by repeating a sequence including TMB+NH₃ plasma (TMB+pNH₃), NH₃ plasma (pNH₃), and purging (PRG) multiple times. As shown in FIG. 5C, in Samples 3 to 5, the BN film was formed on the substrate by repeating a sequence including TMB+NH₃ plasma (TMB+pNH₃), NH₃ plasma (pNH₃), purging (PRG), N₂ plasma modification (pN₂), and purging (PRG) multiple times. In Samples 3 to 5, a time period of the N₂ plasma modification was changed. The modification time period was 1 seconds for Sample 3, 4 seconds for Sample 4, and 16 seconds for Sample 5. As other conditions, the temperature was 400 degrees C., the pressure was 8 Torr, the time period of TMB+pN₂ and TMB+pNH₃ was 2 sec, and the time period of pN₂ and pNH₃ was 4 seconds (was 16 seconds for Sample 5).

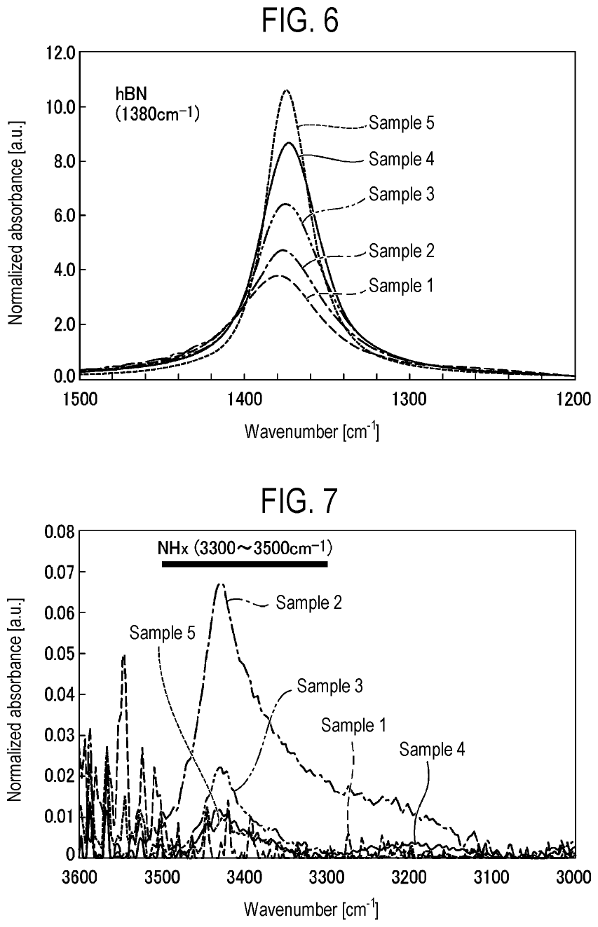

FIG. 6 is a diagram showing the absorbance of each of Samples 1 to 5 in a wavenumber region including a peak of h-BN (1380 cm⁻¹) measured by Fourier transform infrared spectroscopy (FT-IR). As shown in FIG. 6, even in Samples 1 and 2, the h-BN peak was observed, the h-BN peak was increased due to the N₂ plasma modification, and a degree of the increased in the h-BN peak was greatly increased by lengthening the time period of the N₂ plasma modification. In other words, it was confirmed that the lateral orientation of h-BN is improved by the N₂ plasma modification.

FIG. 7 is a diagram showing the absorbance of each of Samples 1 to 5 in a wavenumber region including a peak of NHx (3,300 to 3,500 cm⁻¹) measured by FT-IR. As shown in FIG. 7, it may be appreciated that Sample 2 using the NH₃ plasma during the film formation has a higher NHx peak and a larger amount of H in the film than those in Sample 1 using the N₂ plasma. Meanwhile, it may be appreciated that the NHx peaks of Samples 3 to 5 on which the N₂ plasma modification was performed subsequent to the NH₃ plasma are lower than the NHx peak of Sample 2, and the NHx peaks are further reduced by lengthening the modification time period. Thus, it was confirmed that H in the film is reduced by the N₂ plasma modification.

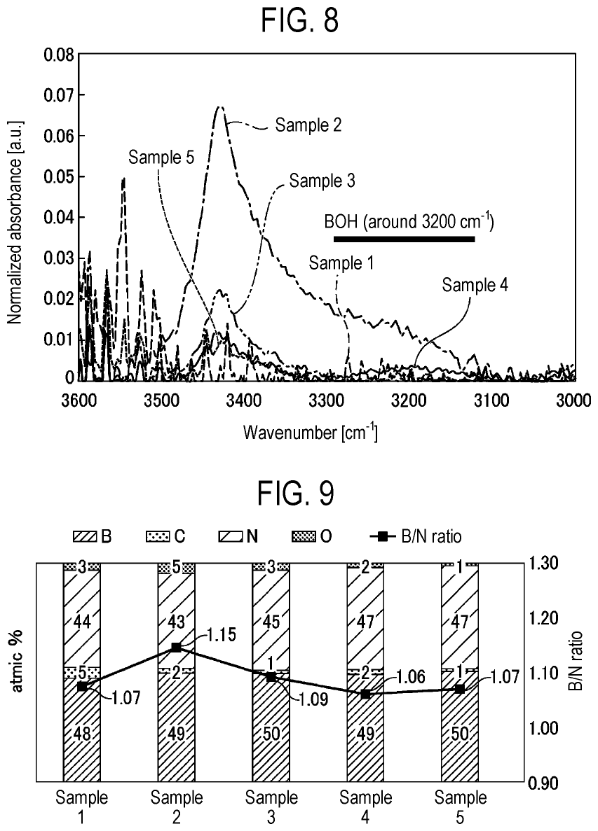

FIG. 8 is a diagram showing the absorbance of each of Samples 1 to 5 in a wavenumber region including a peak of BOH (around 3,200 cm⁻¹) measured by FT-IR. As shown in FIG. 8, although the BOH peak is observed in Sample 2 using the NH₃ plasma during the film formation, the BOH peak is almost not observed in Sample 1 using the N₂ plasma. In other words, it is thought in Sample 2 that BOH derived from atmospheric oxidation was formed due to the presence of NH₃. Meanwhile, the BOH peaks of Samples 3 to 5 on which the N₂ plasma modification was performed subsequent to the NH₃ plasma have decreased compared to that in Sample 2.

FIG. 9 is a diagram showing a film composition and a B/N ratio of the BN film of each of Samples 1 to 5. The BN film is better the fewer impurities such as oxygen and the closer the B/N ratio is to 1. However, as shown in FIG. 9, Sample 2 using the NH₃ plasma has a high amount of oxygen of 5 at % and a high B/N ratio of 1.15 which is B-rich. This is thought to be because BOH is generated in Sample 2 and thus the bond of a BN ring is broken, thereby causing the desorption of N. Meanwhile, Samples 3 to 5 on which the N₂ plasma modification was performed subsequent to the NH₃ plasma have a reduced amount of oxygen and an improved B/N ratio of 1.06 to 1.09. In particular, the amount of oxygen in Sample 5 on which the N₂ plasma modification was performed for 16 seconds decreased to 1 at %.

From the results of FIGS. 8 and 9, in Sample 2 using the NH₃ plasma, since the generation of BOH was observed and thus the oxidation resistance was insufficient, the amount of oxygen in the film was high and the B/N ratio was also high. However, it was confirmed that, by performing the N₂ plasma modification, the oxidation resistance was improved, the amount of oxygen in the film was decreased, and the B/N ratio was also improved.

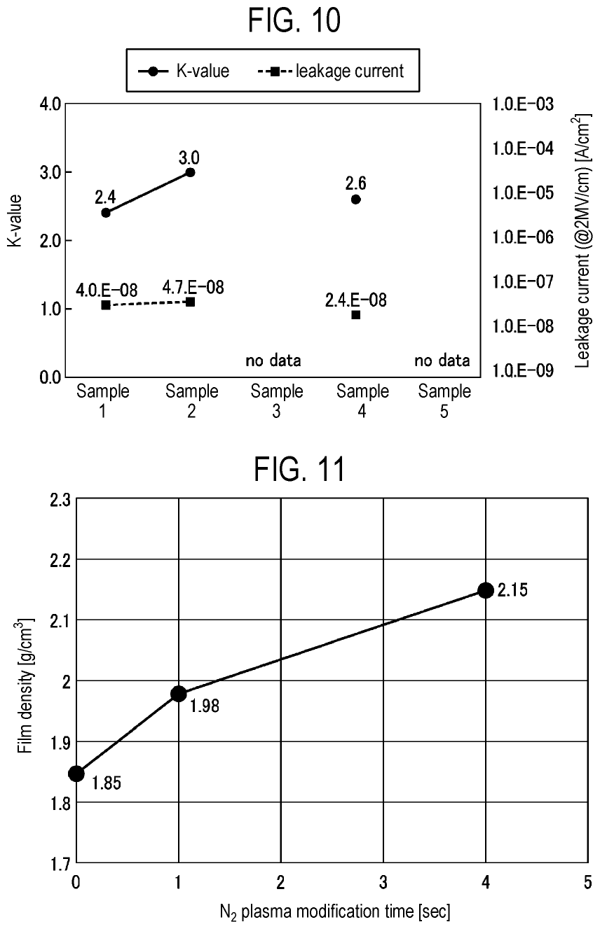

FIG. 10 is a diagram showing the k-value and the leakage current of each of Samples 1 to 5. As shown in FIG. 10, in Sample 2 using the NH₃ plasma, the k-value is 3.0, which is higher than that of Sample 1, and the leakage current value is 4.7E-08A/cm², which is almost the same as that of Sample 1. Meanwhile, in Sample 4 on which the N₂ plasma modification was performed subsequent to the NH₃ plasma, the k-value was reduced to 2.6 and the leakage current value was reduced to 2.4E-08A/cm².

FIG. 11 is a diagram showing a relationship between the N₂ plasma modification time period after the NH₃ plasma and the film density. A value at which the N₂ plasma modification time period is 0 second corresponds to Sample 2 on which the N₂ plasma modification was not performed. As shown in FIG. 11, when the N₂ plasma modification was not performed, the film density was 1.85 g/cm³ but was increased to 2.15 g/cm³ by the N₂ plasma modification performed for 4 seconds.

From the results of FIGS. 9 to 11, it was confirmed that, when the N₂ plasma modification is performed after the film formation using the NH₃ plasma, the k-value and the value of the leakage current are decreased, the film density is increased. Thus, it was confirmed that the N₂ plasma modification has an effect of improving the film quality.

Like the sequences shown in FIGS. 1 to 3, all of the sequences may include step ST2 of supplying the source gas and the plasma of the H-containing gas, step ST3 of supplying the plasma of the H-containing gas alone, and step ST5 of supplying the plasma of the H-free gas to perform the modification process. Alternatively, some of the sequences shown in FIGS. 1 to 3 may include such steps ST2, ST3 and ST5. In this case, the remaining sequence(s) may include an operation of supplying the source gas containing the borazine-based compound and the plasma to the substrate, and subsequently, an operation of supplying the plasma to the substrate without the source gas.

For example, the modification process using the plasma of the H-free gas in step ST5 may be omitted in the sequence including steps ST2 and ST3. That is, for example, when the sequence including steps ST2 and ST3 is performed a predetermined number of times (e.g., 2 to 10 times), the modification process may be performed periodically once.

In addition, in a portion of plurality of sequences, the plasma of the H-containing gas in steps ST2 and ST3 (for example, the NH₃ plasma) may be replaced with the plasma of the H-free gas (for example, the N₂ plasma). In such a sequence, the plasma modification process may be omitted. For example, the sequence shown in FIG. 1 (or the sequence shown in FIG. 2 or 3) may be performed in an initial film-formation stage in which the adhesion or flatness is particularly required, and the sequence using the plasma of the H-free gas (e.g., the N₂ plasma) may be performed in a bulk film-formation stage. In this case, for example, after the sequence using the NH₃ plasma in the initial film-formation stage, the NH₃ plasma in the bulk film-formation stage is not entirely replaced with the N₂ plasma. A transition period including plurality of sequences may be set between the initial film-formation stage and the bulk film-formation stage. A frequency of the N₂ plasma relative to the NH₃ plasma may be gradually increased from the initial film-formation stage to the bulk film-formation stage. In addition, in the transition period, a portion of the NH₃ gas as the plasma gas may be replaced with the N₂ gas, and a proportion of the N₂ gas may be gradually increased from the initial film-formation stage to the bulk film-formation stage so that the NH₃ plasma is transited to the N₂ plasma.

### <Film Forming Apparatus>

Next, an example of a film forming apparatus applicable to the BN film forming method will be described.

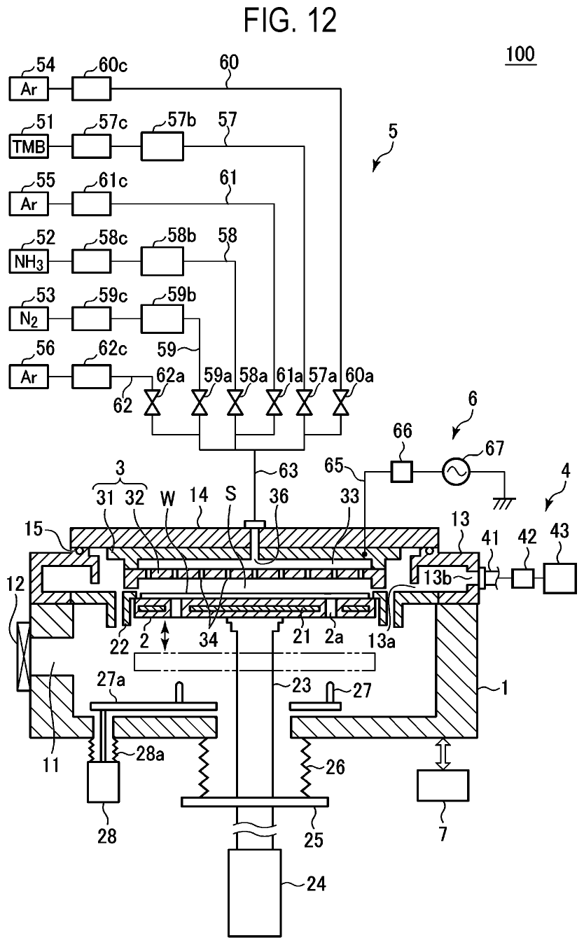

FIG. 12 is a cross-sectional view showing an example of the film forming apparatus.

A film forming apparatus 100 includes a chamber 1, a stage 2, a shower head 3, an exhauster 4, a gas supply mechanism 5, a plasma generation unit 6, and a controller 7, and forms a BN film on a substrate W. The substrate W is not particularly limited but may be, for example, a semiconductor substrate such as a Si substrate.

The chamber 1 is made of a metal such as aluminum and has a substantially cylindrical shape. A loading/unloading port 11 for loading/unloading the substrate W therethrough is formed in a sidewall of the chamber 1 and may be opened/closed by a gate valve 12. An annular exhaust duct 13 having a rectangular cross section is provided on a main body of the chamber 1. A slit 13a is formed along an inner peripheral surface of the exhaust duct 13. An exhaust port 13b is formed in an outer wall of the exhaust duct 13. A ceiling wall 14 is provided on a top surface of the exhaust duct 13 to close an upper opening of the chamber 1. A space between the ceiling wall 14 and the exhaust duct 13 is hermetically sealed with a seal ring 15.

The stage 2 on which the substrate W is placed in a horizontal posture is formed in a disk shape of a size corresponding to the substrate W and is supported by a support member 23. The stage 2 is made of a ceramic material such as aluminum nitride (AlN) or a metallic material such as aluminum or a nickel-based alloy. A heater 21 for heating the substrate W is embedded in the stage 2. The stage 2 is provided with a cover member 22 to cover a side surface thereof.

The support member 23 supporting the stage 2 extends downward from the center of a bottom surface of the stage 2 via a hole formed in a bottom wall of the chamber 1. A lower end of the support member 23 is connected to a stage lifting mechanism 24. The stage 2 is configured to be raised/lowered by the stage lifting mechanism 24 via the support member 23 between a processing position indicated by a solid line and a substrate transfer position indicated by a dash-dotted line below the processing position. A flange 25 is installed at the support member 23 below the chamber 1. A bellows 26 configured to isolate an internal atmosphere of the chamber 1 from ambient air and to be flexible with a vertical movement of the stage 2 is provided between the bottom surface of the chamber 1 and the flange 25.

Three substrate support pins 27 (only two of which are shown) are provided near the bottom surface of the chamber 1 to protrude upward from a lifting plate 27a. The substrate support pins 27 are configured so as to be raised/lowered via the lifting plate 27a by a substrate support pin lifting mechanism 28 provided below the chamber 1 and to move upward and downward with respect to an upper surface of the stage 2 by being inserted into respective through-holes 2a provided in the stage 2 located at the transfer position. By raising/lowering the substrate support pins 27 in this way, the substrate W is delivered between a substrate transfer mechanism (not shown) and the stage 2. A bellows 28a is provided between the bottom surface of the chamber 1 and the substrate support pin lifting mechanism 28.

The shower head 3 supplies a processing gas into the chamber 1 in the form of a shower. The shower head 3 is provided to face the stage 2 and has almost the same diameter as that of the stage 2. The shower head 3 includes a shower body 31 fixed to the ceiling wall 14 of the chamber 1 and a shower plate 32 connected below the shower body 31. A gas diffusion space 33 is formed between the shower body 31 and the shower plate 32. A gas introduction hole 36 provided to penetrate the center of the shower body 31 and the ceiling wall 14 of the chamber 1 is connected to the gas diffusion space 33. Gas ejection holes 34 are formed in the shower plate 32. When the stage 2 is at the processing position, a processing space S is formed between the shower plate 32 and the stage 2.

The exhauster 4 is provided with an exhaust pipe 41 connected to the exhaust port 13b of the exhaust duct 13, an automatic pressure control (APC) valve 42 connected to the exhaust pipe 41, and an exhaust mechanism 43 equipped with a vacuum pump. During processing, gas in the chamber 1 reaches the exhaust duct 13 via the slit 13a and is exhausted from the exhaust duct 13 via the exhaust pipe 41 by the exhaust mechanism 43 of the exhauster 4.

The gas supply mechanism 5 supplies gas for film formation to the shower head 3 and supplies the source gas containing the borazine-based compound, the plasma of the H-containing gas, the plasma of the H-free gas for modification process, and the purge gas. As described above, an example is shown herein in which TMB is used as the borazine-based compound, the NH₃ gas is used as the plasma of the H-containing gas, the N₂ gas is used as the plasma gas for modification process not containing H, and the Ar gas is used as the purge gas. However, as described above, the borazine-based compound, the plasma of the H-containing gas, the plasma of the H-free gas for modification process, and the purge gas are not limited thereto.

The gas supply mechanism 5 includes a TMB gas source 51 configured to supply the TMB gas as the source gas, an NH₃ gas source 52 configured to supply the NH₃ gas as the H-containing gas to generate plasma for film formation, and an N₂ gas source 53 configured to supply the N₂ gas as the H-free gas to generate plasma for modification. Further, the gas supply mechanism 5 includes a first Ar gas source 54, a second Ar gas source 55, and a third Ar gas source 56 which are configured to supply the Ar gas as the purge gas.

One end of a TMB gas line 57 is connected to the TMB gas source 51. A valve 57a, a fill tank 57b, and a flow rate adjuster 57c are provided in the TMB gas line 57 in this order from a downstream side. One end of an NH₃ gas line 58 is connected to the NH₃ gas source 52. A valve 58a, a fill tank 58b, and a flow rate adjuster 58c are provided in the NH₃ gas line 58 in this order from a downstream side. One end of an N₂ gas line 59 is connected to the N₂ gas source 53. A valve 59a, a fill tank 59b, and a flow rate adjuster 59c are provided in the N₂ gas line 59 in this order from a downstream side. The TMB gas line 57, the NH₃ gas line 58, and the N₂ gas line 59 are connected to one end of a common line 63, and the other end of the common line 63 is connected to the gas introduction hole 36 of the shower head 3.

One end of a first Ar gas line 60 is connected to the first Ar gas source 54. A valve 60a and a flow rate adjuster 60c are provided in the first Ar gas line 60 in this order from a downstream side. The other end of the first Ar gas line 60 is connected to the downstream side of the valve 57a of the TMB gas line 57. One end of a second Ar gas line 61 is connected to the second Ar gas source 55. A valve 61a and a flow rate adjuster 61c are provided in the second Ar gas line 61 in this order from a downstream side. The other end of the second Ar gas line 61 is connected to the downstream side of the valve 58a of the NH₃ gas line 58. One end of a third Ar gas line 62 is connected to the third Ar gas source 56. A valve 62a and a flow rate adjuster 62c are provided in the third Ar gas line 62 in this order from a downstream side. The other end of the third Ar gas line 62 is connected on the downstream side of the valve 59a of the N₂ gas line 59. During the film formation process, the valves 60a, 61a, and 62a are open at all times so that the Ar gas as the purge gas is constantly supplied into the chamber 1 from the first Ar gas line 60, the second Ar gas line 61, and the third gas line 62 via the TMB gas line 57, the NH₃ gas line 58, and the N₂ gas line 59.

The valves 57a, 58a, and 59a are configured as high-speed opening/closing valves which open and close respective gas lines at high speed. The valves 60a, 61a, and 62a may be normal opening/closing valves.

The fill tanks 57b, 58b, and 59b temporarily store the TMB gas, the NH₃ gas, and the N₂ gas, respectively, before supplying the gases into the chamber 1. By storing the gases in the fill tanks 57b, 58b, and 59b, an internal pressure of the tanks is increased to a predetermined pressure, and then the valves 57a, 58a, and 59a are open to eject the gases into the chamber 1. Thus, a large flow rate of gas may be stably supplied to the chamber 1.

The flow rate adjusters 57c, 58c, 59c, 60c, 61c, and 62c are constituted with, for example, mass flow controllers, and configured to adjust and control flow rates of the gases flowing through the respective gas lines.

The plasma generation unit 6 includes a power supply line 65 connected to the shower body 31 of the shower head 3, and a matcher 66 and an RF power source 67 connected to the power supply line 65. When RF power is supplied from the RF power source 67 to the shower head 3, an RF electric field is formed in the processing space S between the shower head 3 and the stage 2. The RF electric field generates capacitively-coupled plasma. When the stage 2 is made of a ceramic material, an electrode is embedded in the stage 2, and an RF electric field is formed between the shower head 3 and the electrode.

The controller 7 is configured as a computer and is provided with a main controller including a CPU, an input device, an output device, a display device, and a storage device (storage medium). The main controller controls components of the film forming apparatus 100, for example, the valves, the flow rate adjusters, the automatic pressure control valves, the heater, and the lifting mechanism. The storage device stores parameters for various processes performed by the film forming apparatus 100. In addition, the storage device includes a storage medium storing a program for controlling the processes performed by the film forming apparatus 100, that is, a processing recipe. The main controller calls a predetermined processing recipe stored in the storage medium and causes the film forming apparatus 100 to execute a predetermined operation based on the processing recipe.

In the film forming apparatus 100 configured as above, first, the gate valve 12 is open, and the substrate W is loaded into the chamber 1 via the loading/unloading port 11 by the transfer device (not shown) and placed on the stage 2. The transfer device is retracted, and the stage 2 is raised to the processing position. Then, the gate valve 12 is closed to exhaust the interior of the chamber 1, and the temperature (substrate temperature) of the stage 2 is controlled to be heated to a desired temperature by the heater 21.

In this state, an actual film formation process is started.

When performing the above-described sequence shown in FIG. 1, first, the Ar gas is supplied as the purge gas from the first Ar gas source 54, the second Ar gas source 55, and the third Ar gas source 56 to the processing space S via the first Ar gas line 60, the second Ar gas line 61, the third Ar gas line 62, and the shower head 3 to purge the chamber 1 in step ST1 (step ST1). In this case, the NH₃ gas, which is a plasma gas, may be supplied. In addition, the TMB gas, which is a source gas, may be filled into the fill tank, or flow into the exhaust line to prepare for supply.

Subsequently, the TMB gas and the NH₃ plasma are supplied to the substrate W (step ST2). Specifically, RF power is supplied from the RF power source 67 of the plasma generation unit 6 to the shower head 3 in a state in which the NH₃ gas as the plasma gas is supplied from the NH₃ gas source 52 to the processing space S via the NH₃ gas line 58 and the shower head 3 while the Ar gas is being supplied. As a result, the NH₃ plasma is generated in the processing space S. In addition, the TMB gas, which is a source gas, is supplied from the TMB gas source 51 to the processing space S via the TMB gas line 57 and the shower head 3. As a result, the TMB gas and the NH₃ plasma are supplied to the substrate W. The TMB gas is adsorbed onto the substrate W, and the TMB gas in a gas phase and in the film is activated by the NH₃ plasma to promote adsorption thereof.

After step ST2 is completed, while continuing to generate the NH₃ plasma, the valve 57a is closed to stop the supply of the TMB gas, and the NH₃ plasma alone is supplied to the substrate W (step ST3). This further activates the TMB gas in the film, thereby promoting the adsorption of the TMB gas and promoting the reaction of the TMB gas to h-BN.

Subsequently, the RF power from the RF power source 67 is turned off, the valve 58a is closed to stop the supply of the NH₃ gas, and the interior of the chamber 1 is purged with the Ar gas supplied thereto (step ST4). In this case, the valve 59a may be opened to supply the N₂ gas as the plasma gas for modification process from the N₂ gas source 53 to the processing space S via the N₂ gas line 59 and the shower head 3.

Subsequently, the RF power from the RF power source 67 is turned on, and the N₂ gas continues to be supplied to generate the N₂ plasma in the processing space S, and the modification process is performed by the N₂ plasma (step ST5).

Thereafter, the RF power from the RF power source 67 is turned off, the valve 59a is closed to stop the supply of the N₂ gas, and the interior of the chamber 1 is purged with the Ar gas supplied thereto (step ST6).

The sequence including steps ST1 to ST6 described above is repeated a predetermined number of cycles to form an h-BN film having a desired thickness.

In addition, as shown in FIG. 2, when the pre-plasma step (step ST7) is performed prior to step ST2, step ST7 may be performed in the same manner as step ST3. In addition, as shown in FIG. 3, when the pre-flow step (step ST8) is performed instead of step ST1, the same borazine-based compound gas as in step ST2 is supplied without using plasma.

Further, as described above, all sequences may not include steps ST1 to ST6 (or the sequence of FIG. 2 or 3), and a portion of the sequences may not include the modification process using the N₂ plasma or may use the N₂ plasma as plasma during the film formation and plasma after the film formation.

As described above, in the operation of supplying the TMB gas and the plasma and the operation of supplying the plasma without the TMB gas, the NH₃ plasma is used as the plasma. Thus, the adhesion of the h-BN film formed and the flatness of the film surface are improved. In addition, by the subsequent modification process using the N₂ plasma, H in the film is reduced and thus the h-BN film with good film quality is obtained.

### OTHER APPLICATIONS

It should be noted that the embodiments disclosed herein are exemplary in all respects and are not restrictive. The above-described embodiments may be omitted, replaced or modified in various forms without departing from the scope and spirit of the appended claims.

For example, in the above embodiment, each of the sequences shown as defaults in FIGS. 1 to 3 includes the operation of supplying the borazine-based compound gas and plasma of the H-containing gas (step ST2), the operation of supplying the plasma of the H-containing gas (step ST3), the purging operation (step ST4), the operation of performing the modification process using the plasma of the H-free gas (step ST5), and the purging operation (step ST6). However, such default sequence is not particularly limited as long as it includes the operation of supplying the borazine-based compound gas and the plasma of the H-containing gas to the substrate, subsequently the operation of supplying the plasma of the H-containing gas to the substrate, and the operation of performing the modification process using the plasma of the H-free gas. As described above, all of the plurality of sequences are not limited to the above default sequence. For example, a portion of the plurality of sequences may be different from the default sequence as long as it includes the operation of supplying the source gas containing the borazine-based compound gas and the plasma to the substrate, and subsequently, the operation of supplying the plasma to the substrate without the source gas.

The film forming apparatus shown in FIG. 12 is merely exemplary and is not particularly limited as long as it sequentially performs step ST2 of supplying the borazine-based compound gas and the plasma of the H-containing gas, step ST3 of supplying the plasma of the H-containing gas, and step ST5 of performing the modification process using the plasma of the H-free gas. The film forming apparatus may be of a batch type without being limited to a single-wafer type. In addition, while the film forming apparatus 100 of FIG. 12 shows an example in which RF power is supplied to the shower head 3 to generate capacitively-coupled plasma between the shower head 3 and the stage 2, the film forming apparatus 100 is not limited the example and various plasma such as inductively-coupled plasma or microwave plasma may be used. Further, plasma, which is remotely generated elsewhere and transferred to the substrate, may be used.

According to the present disclosure in some embodiments, there is provided a boron nitride film forming method and a film forming apparatus capable of forming a hexagonal boron nitride film having good adhesion, flatness and film quality.

What is claimed is:

1. A method of forming a boron nitride film, the method comprising:
performing a plurality of sequences, each of the plurality of sequences including supplying a source gas containing a borazine-based compound and plasma to a substrate disposed inside a chamber and subsequently supplying the plasma to the substrate without the source gas,
wherein each of at least a portion of the plurality of sequences includes supplying plasma of a hydrogen-free gas to the substrate after the supplying the plasma without the source gas,
wherein the supplying the source gas containing the borazine-based compound and the plasma includes supplying the source gas and plasma of a hydrogen-containing gas to the substrate, and
wherein the supplying the plasma without the source gas includes supplying the plasma of the hydrogen-containing gas without the source gas.

2. The method of claim 1, wherein each of the plurality of sequences includes:
purging an interior of the chamber;
subsequently, the supplying the source gas and the plasma of the hydrogen-containing gas to the substrate;
subsequently, the supplying the plasma of the hydrogen-containing gas to the substrate without the source gas;
subsequently, purging the interior of the chamber;
subsequently, the supplying the plasma of the hydrogen-free gas to the substrate; and
purging the interior of the chamber.

3. The method of claim 1, wherein each of the plurality of sequences includes:
purging an interior of the chamber;
subsequently, supplying the plasma of the hydrogen-containing gas to the substrate;
subsequently, the supplying the source gas and the plasma of the hydrogen-containing gas to the substrate;
subsequently, the supplying the plasma of the hydrogen-containing gas to the substrate without the source gas;
subsequently, purging the interior of the chamber;
subsequently, the supplying the plasma of the hydrogen-free gas to the substrate; and
subsequently, purging the interior of the chamber.

4. The method of claim 1, wherein each of the plurality of sequences includes:
supplying the source gas to the substrate;
subsequently, the supplying the source gas and the plasma of the hydrogen-containing gas to the substrate;
subsequently, the supplying the plasma of the hydrogen-containing gas to the substrate without the source gas;
subsequently, purging an interior of the chamber;
subsequently, the supplying the plasma of the hydrogen-free gas to the substrate; and
subsequently, purging the interior of the chamber.

5. The method of claim 1, wherein the borazine-based compound is an alkylborazine compound.

6. The method of claim 5, wherein the borazine-based compound is trimethylborazine.

7. The method of claim 1, wherein the hydrogen-containing gas includes hydrogen and nitrogen.

8. The method of claim 7, wherein the hydrogen-containing gas is an ammonia gas.

9. The method of claim 1, wherein the hydrogen-free gas is at least one selected from a group consisting of a nitrogen gas and a noble gas.

10. The method of claim 1, wherein a first sequence of the at least a portion of the plurality of sequences includes the supplying the source gas and the plasma of the hydrogen-containing gas to the substrate, the supplying the plasma of the hydrogen-containing gas to the substrate without the source gas, and the supplying the plasma of the hydrogen-free gas to the substrate, and
wherein a second sequence of the at least a portion of the plurality of sequences includes the supplying the source gas and the plasma of the hydrogen-containing gas to the substrate, and the supplying the plasma of the hydrogen-containing gas to the substrate without the source gas, and does not include the supplying the plasma of the hydrogen-free gas to the substrate.

11. The method of claim 10, wherein the supplying the plasma of the hydrogen-free gas to the substrate is periodically performed.

12. The method of claim 1, wherein a first sequence of the at least a portion of the plurality of sequences includes: the supplying the source gas and the plasma of the hydrogen-containing gas to the substrate; the supplying the plasma of the hydrogen-containing gas to the substrate without the source gas; and the supplying the plasma of the hydrogen-free gas to the substrate, and
wherein a second sequence of the at least a portion of the plurality of sequences includes: supplying the source gas and the plasma of the hydrogen-free gas to the substrate; and subsequently, supplying the plasma of the hydrogen-free gas to the substrate without the source gas.

13. The method of claim 12, wherein a third sequence of the at least a portion of the plurality of sequences including the supplying the source gas and the plasma of the hydrogen-containing gas to the substrate, the supplying the plasma of the hydrogen-containing gas to the substrate without the source gas, and the supplying the plasma of the hydrogen-free gas to the substrate is performed in an initial film-formation stage, and
wherein a fourth sequence of the at least a portion of the plurality of sequences including the supplying the source gas and the plasma of the hydrogen-free gas to the substrate and subsequently the supplying the plasma of the hydrogen-free gas to the substrate without the source gas is performed in a bulk film-formation stage.

14. The method of claim 13, wherein a transition period to which the plurality of sequences is set is provided between the initial film-formation stage and the bulk film-formation stage, and
wherein, in the transition period, a frequency of the plasma of the hydrogen-free gas is gradually increased from the initial film-formation stage to the bulk film-formation stage, or a portion of the hydrogen-containing gas is replaced with the hydrogen-free gas so that a proportion of the hydrogen-free gas is increased from the initial film-formation stage to the bulk film-formation stage.

15. An apparatus for forming a boron nitride film, comprising:
a chamber in which a substrate is accommodated;
a gas supply mechanism configured to supply a source gas containing a borazine-based compound and a gas for plasma generation into the chamber;
an exhaust mechanism configured to exhaust an interior of the chamber;
a plasma generation unit configured to generate plasma;
a heater configured to heat the substrate; and
a controller,
wherein the controller is configured to execute plurality of sequences, each of the plurality of sequences including supplying the source gas containing the borazine-based compound and the plasma to the substrate disposed inside the chamber and subsequently supplying the plasma to the substrate without the source gas,
wherein each of at least a portion of the plurality of sequences includes supplying plasma of a hydrogen-free gas to the substrate after the supplying the plasma without the source gas,
wherein the supplying the source gas containing the borazine-based compound and the plasma includes supplying the source gas and plasma of a hydrogen-containing gas to the substrate, and
wherein the supplying the plasma without the source gas includes supplying the plasma of the hydrogen-containing gas without the source gas.
